(19) United States
(12) Patent Application Publication
(10) Pub. No.: US 2017/0031632 A1
(43) Pub. Date: Feb. 2, 2017

(54) DATA STORAGE DEVICE, METHOD OF OPERATING THE SAME, AND DATA PROCESSING SYSTEM INCLUDING THE SAME

(71) Applicant: SAMSUNG ELECTRONICS CO., LTD., Suwon-si (KR)

(72) Inventors: Hyun Sik YUN, Hwaseong-si (KR); Sang Yoon OH, Suwon-si (KR); Myung Jin JUNG, Yongin-si (KR); Hyun Jin CHOI, Suwon-si (KR)

(73) Assignee: SAMSUNG ELECTRONICS CO., LTD., Suwon-si (KR)

(21) Appl. No.: 15/201,761

(22) Filed: Jul. 5, 2016

(30) Foreign Application Priority Data
Jul. 28, 2015 (KR) 10-2015-0106733

(51) Int. Cl. G06F 3/06; G11C 16/26; G06F 12/1009; G11C 16/10

(52) U.S. Cl. CPC G06F 3/0659; G11C 16/10; G11C 16/26; G06F 12/1009; G06F 3/0619; G06F 3/0685; G06F 2212/7201

(57) ABSTRACT

A data storage device includes a non-volatile memory device and a controller configured to receive a command from a host and to control an operation of the non-volatile memory device based on the command. The controller includes a processor configured to receive and process the command and an address extractor configured to extract address information from the command and to output the address information to the processor before the processor processes the command.

### CROSS-REFERENCE TO RELATED APPLICATION

This application claims priority under 35 U.S.C. §119(a) from Korean Patent Application No. 10-2015-0106733, filed on Jul. 28, 2015 in the Korean Intellectual Property Office, the disclosure of which is hereby incorporated by reference in its entirety.

### BACKGROUND

Apparatuses and methods consistent with exemplary embodiments relate to a data storage device, and more particularly, to a data storage device for realizing parallel executions, a method of operating the same, and a data processing system including the same.

Memory devices may be categorized as volatile memory devices and non-volatile memory devices. Volatile memory devices maintain data while the device is powered, whereas non-volatile memory devices maintain data even after having been power cycled.

A flash memory device is an example of electrically erasable programmable read-only memory (EEPROM) in which a plurality of memory cells are erased or programmed in one program operation.

A flash translation layer (FTL) is software for efficiently managing a flash memory device. The FTL is included in a memory controller and translates a logical address into a physical address of the flash memory device. The FTL has a mapping table for the translation. The mapping table includes information about mapping between a logical address and a physical address.

When a drive includes flash memory devices, the number of flash memory devices needs to be increased in order to increase the capacity of the drive. As the number of flash memory devices included in the drive increases, the capacity or size of a mapping table also needs to be increased. Due to capacity and processing speed of memory storing the mapping table, the number of flash memory devices may be limited. In other words, when a memory resource is not sufficient for the FTL to load all mapping tables, mapping tables are loaded as needed during the operation of a flash memory device. As a result, the input/output performance of the drive may deteriorate.

### SUMMARY

According to an aspect of an exemplary embodiment, there is provided a data storage device including: a non-volatile memory device; and a controller configured to receive a command from a host and to control an operation of the non-volatile memory device based on the command, the controller including a processor configured to receive and process the command and an address extractor configured to extract address information from the command and to output the address information to the processor before the processor processes the command.

The processor may include: a first core configured to generate a sub-command based on the command; and a plurality of second cores configured to receive the sub-command output from the first core.

The sub-command may correspond to commands for controlling peripheral devices comprised in the data storage device to perform one among a read operation and a write operation of the non-volatile memory device.

The sub-command may correspond to one among a read operation, a write operation, and a trimming operation on peripheral devices comprised in the data storage device.

The address information may include logical address information corresponding to peripheral devices comprised in the data storage device.

The logical address information may include a namespace, a volume, a logical block address, and a length.

The first core may be configured to determine the command at a first time point and the address extractor may be configured to output the address information to the plurality of second cores at the first time point.

The plurality of second cores may be configured to perform an operation of preparing to control peripheral devices comprised in the data storage device at the first time point based on the address information.

The plurality of second cores are configured to determine, at the first time point, whether internal management data corresponding to the address information has been loaded to the controller; and load, in response to the determining indicating the internal management data has not been loaded, the internal management data corresponding to the address information from the non-volatile memory device at a second time point after the first time point.

The sub-command may comprise a command corresponding to an operation of loading the internal management data corresponding to the address information and a command corresponding to an operation of programming the non-volatile memory device based on the internal management data.

The internal management data may include map information corresponding to the address information among information corresponding to a logical address and a physical address which are comprised in a mapping table of the non-volatile memory device.

Each of the plurality of second cores may be configured to determine whether to process the received sub-command based on the address information.

The address information may indicate a selected second core of the plurality of second cores, and only the selected second core processes the received sub-command.

According to an aspect of another exemplary embodiment, there is provided a method of operating a data storage device including a first core, a plurality of second cores and a non-volatile memory device, the method including: receiving a command from a host; extracting address information from the command; determining whether a target designation mode has been set based on the address information extracted from the command; transmitting a request including the address information to the plurality of second cores; and processing, by the first core, the command to generate a sub-command.

The method may further include determining whether the plurality of second cores support a queue format after the determining whether the target designation mode has been set; forming a queue including the request, in response to determining the plurality of second cores support the queue format; and transmitting the request in the queue to the plurality of second cores.

The address information may include logical address information corresponding to peripheral devices comprised in the data storage device; and the logical address information may include a namespace, a volume, a logical block address, and a length.

The method may further include, determining, by each of the plurality of second cores, whether the address information indicates the second core as a selected second core; and processing, by only the selected second core, the request.

According to an aspect of yet another exemplary embodiment, there is provided a method of operating a data storage device including a first core, a second core, a non-volatile memory device and an address extractor, the method including: determining whether the first core is in an idle state; receiving, using the second core, a request output from the address extractor; determining, in response to the first core being in the idle state, using the second core, whether a target designation mode has been set based on the request output from the address extractor; analyzing, in response to the determining indicating the target designation mode is not set, the request to determine a request target; and performing an operation corresponding to the request in response to the analyzing indicating the second core is the request target.

The method may further include performing, by the second core, an operation corresponding to a sub-command output from the first core in response to the determining indicating the first core is not in the idle state.

The second core may be one of a plurality of second cores, and the request target uniquely identifies the second core.

### BRIEF DESCRIPTION OF THE DRAWINGS

The above and other features and advantages will become more apparent from the following description of exemplary embodiments taken in conjunction with the attached drawings in which:

FIG. 1 is a block diagram of a data processing system according to one or more exemplary embodiments;

FIG. 2 is a block diagram of a data storage device illustrated in FIG. 1;

FIG. 3 is a timing chart showing a procedure in which a data storage device processes a command received from a host;

FIG. 4 is a timing chart showing a procedure in which a data storage device processes a command received from a host according to one or more exemplary embodiments;

FIG. 5 is a flowchart of a method of operating a data storage device according to one or more exemplary embodiments;

FIG. 6 is a flowchart of a method of operating a data storage device according to one or more exemplary embodiments;

FIG. 7 is a block diagram of a data processing system according to one or more exemplary embodiments;

FIG. 8 is a block diagram of a data processing system according to one or more exemplary embodiments; and

FIG. 9 is a block diagram of a data processing system according to one or more exemplary embodiments.

### DETAILED DESCRIPTION OF EXEMPLARY EMBODIMENTS

Exemplary embodiments will now be described with reference to the accompanying drawings.

The inventive concept may, however, be embodied in many different forms and should not be construed as limited to the exemplary embodiments set forth herein. Rather, these exemplary embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing exemplary embodiments only and is not intended to be limiting. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Expressions such as “at least one of,” when preceding a list of elements, modify the entire list of elements and do not modify the individual elements of the list.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

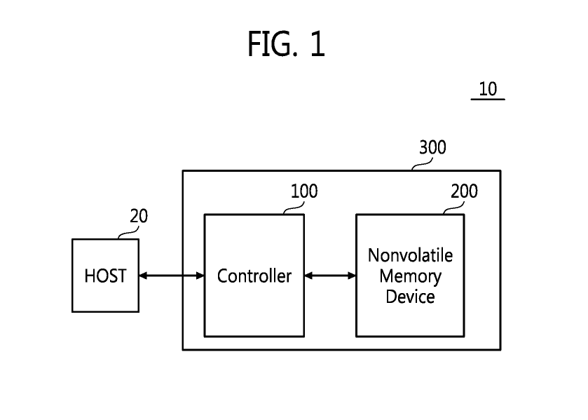

FIG. 1 is a block diagram of a data processing system 10 according to one or more exemplary embodiments. The data processing system 10 may include a host 20 and a data storage device 300. The data storage device 300 may include a controller 100 and a nonvolatile memory device 200. The data processing system 10 may be implemented as a server computer, a personal computer (PC), a desktop computer, a laptop computer, a workstation computer, a network-attached storage (NAS), a data center, an internet data center (IDC), or a mobile computing device. The mobile computing device may be a smart phone, a tablet PC, or a mobile internet device (MID).

The host 20 may communicate with the data storage device 300 using an interface protocol such as serial advanced technology attachment (SATA) interface, SATA express (SATAe) interface, SAS (serial attached small computer system interface (SCSI)), peripheral component interconnect express (PCIe) interface, non-volatile memory express (NVMe) interface, or advanced host controller interface (AHCI). The host 20 may control a data processing operation (e.g., a write operation or a read operation) of the data storage device 300.

The data storage device 300 may be implemented as a flash memory-based data storage device, but is not restricted to this example. For instance, the data storage device 300 may be implemented as a solid-state drive or solid-state disk (SSD), an embedded SSD (eSSD), a universal flash storage (UFS), a multimedia card (MMC), or an embedded MMC (eMMC), but is not restricted to these examples. The flash memory-based data storage device may be a NAND-type flash memory device or a NOR-type flash memory device. Alternatively, the data storage device 300 may be implemented as a hard disk drive (HDD), a phase-change random access memory (PRAM) device, a magnetoresistive RAM (MRAM) device, a spin-transfer torque MRAM (STT-MRAM) device, a ferroelectric RAM (FRAM) device, or a resistive RAM (RRAM) device, but the types of the data storage device 300 are not restricted to these examples.

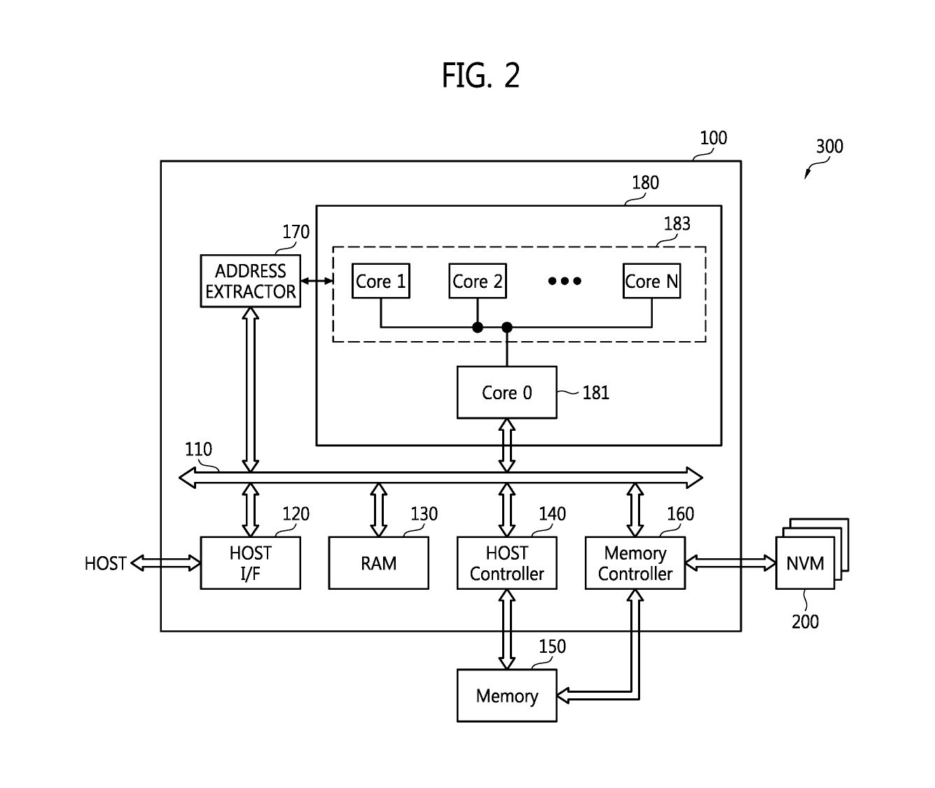

FIG. 2 is a block diagram of the data storage device 300 illustrated in FIG. 1. Referring to FIGS. 1 and 2, the data storage device 300 may include the controller 100, a memory 150, and the non-volatile memory (NVM) device 200. The controller 100 may include a host interface (I/F) 120, a RAM 130, a host controller 140, a memory controller 160, an address extractor 170, and a processing unit 180 (processor).

The host I/F 120, the RAM 130, the host controller 140, the memory controller 160, the address extractor 170, and the processing unit 180 may communicate a command and/or data with one another through bus architecture 110. The bus architecture 110 may be implemented using advanced microcontroller bus architecture (AMBA), advanced extensible interface (AXI), or advanced high-performance bus (AHB), but is not restricted thereto.

The host I/F 120 may transmit a response and/or data to the host 20. The host I/F 120 may also receive a command and/or data from the host 20 and transmit the command and/or data to the processing unit 180.

The RAM 130 may store data for the operation of the controller 100 or data generated from a data processing operation (such as a write operation or a read operation) performed by the controller 100. The RAM 130 may also include a first region for loading and storing a mapping table for logical address-to-physical address translation for the NVM device 200, and a second region functioning as a cache.

The mapping table may be a flash translation layer (FTL) mapping table. The processing unit 180 may execute an FTL and the FTL may perform logical address-to-physical address translation or mapping using the FTL mapping table.

The host controller 140 may write data to or read data from the memory 150 according to the control of the processing unit 180. The host controller 140 may directly perform, in association with the NVM device 200, a data processing operation (such as a write operation or a read operation) corresponding to a command (such as a write command or a read command) stored in the RAM 130 using direct memory access (DMA). The data processing operation may be performed on each DMA unit. The host controller 140 may be an NVM express (NVMe), NVM host controller interface specification (NVMHCI) controller or a small computer system interface express (SCSIe) controller but is not restricted to these examples.

The memory 150 may be formed of volatile memory such as dynamic RAM (DRAM). Although the RAM 130 and the memory 150 are separated from each other in the exemplary embodiments illustrated in FIG. 2, the RAM 130 and the memory 150 may be integrated into one memory, or the RAM 130 may be part of the memory 150 in other exemplary embodiments.

The memory controller 160 may write data to or read data from the memory 150 according to the control of the processing unit 180. The memory controller 160 may also write data to or read data from the NVM device 200 according to the control of the processing unit 180 and/or the host controller 140. When the NVM device 200 is a flash memory device, the memory controller 160 may function as a flash memory controller.

The processing unit 180 may control the operations of the host I/F 120, the RAM 130, the host controller 140, and the memory controller 160 through the bus architecture 110. The processing unit 180 may include a first core 181 and a plurality of second cores 183. The first core 181 may control the operation of the host I/F 120 and the second cores 183 may control the operation of the host controller 140 and/or the memory controller 160.

The processing unit 180 may receive a command from the host 20 and may perform a data processing operation corresponding to the command. The first core 181 may determine the command and output sub-commands to the second cores 183 based on the determination result. The second cores 183 may receive the sub-commands from the first core 181 and process the sub-commands.

In detail, the first core 181 may output sub-commands to one of the second cores 183 based on the command received from the host 20. Each of the second cores 183 may control the operation of the NVM device 200 based on sub-commands received from the first core 181. The sub-commands may include a command for controlling a read operation of the NVM device 200 and a command for controlling a write operation of the NVM device 200. The sub-commands may also include commands for controlling the host I/F 120, the RAM 130, the host controller 140, the memory 150, and the memory controller 160 to perform the read and write operations of the NVM device 200. For instance, the sub-commands may include commands respectively corresponding to read, write and trimming operations.

The address extractor 170 may extract address information from a command transmitted from the host 20 to the first core 181 and transmit the address information to the second cores 183 before the processing unit 180 processes the command. The address information may include logical address information corresponding to the host I/F 120, the RAM 130, the host controller 140, the memory 150, and the memory controller 160. The logical address information may include a namespace, a volume, a logical block address, and a length.

The NVM device 200 may be formed of flash memory, such as NAND flash memory or NOR flash memory, but is not restricted to these examples.

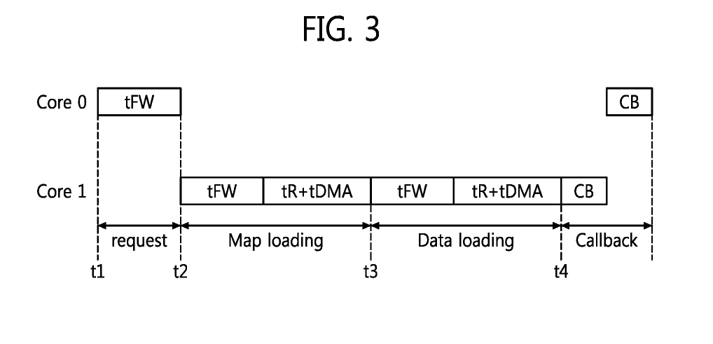

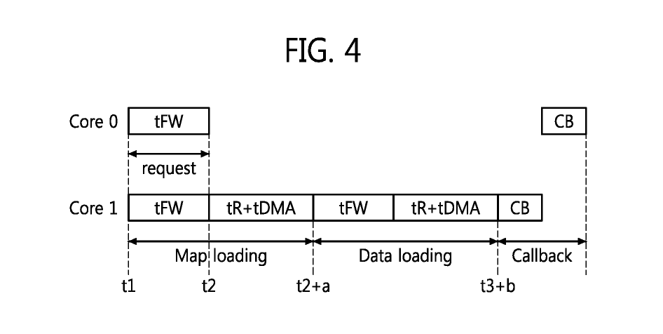

FIG. 3 is a timing chart showing a procedure in which a data storage device processes a command received from a host. FIG. 4 is a timing chart showing a procedure in which a data storage device processes a command received from a host according to one or more exemplary embodiments. It is assumed that a read operation is performed on the NVM device 200 illustrated in FIG. 3 and the exemplary embodiments illustrated in FIG. 4.

Referring to FIG. 3, during a first period tFW from a first time point t1 to a second time point t2, the first core 181 may output sub-commands to one of the second cores 183 based on a command issued from the host 20. The second core 183 may determine whether internal management data corresponding to the sub-commands has been loaded to the RAM 130 during a second period tFW, and may load the internal management data corresponding to the sub-commands from the NVM device 200 during a third period “tR+tDMA”.

Thereafter, the second core 183 may perform a read operation on the NVM device 200 during a fourth period tFW based on the internal management data and may output data read from the NVM device 200 to the host 20 during a fifth period “tR+tDMA”. After the read operation of the NVM device 200 is completed, the second core 183 may output a callback message CB to the host 20 through the first core 181.

In contrast, as illustrated in FIG. 4, while the first core 181 determines a command issued from the host 20 at the first time point t1, the address extractor 170 may extract address information from the command and output the address information to the second core 183. The second core 183 may perform an operation of preparing to load internal management data from the NVM device 200 at the first time point t1 based on the address information, and may load the internal management data corresponding to the address information at the second time point t2. In detail, the second core 183 may determine whether the internal management data corresponding to the address information has loaded to the RAM 130 at the first time point t1, and may load the internal management data corresponding to the address information from the NVM device 200 at the second time point t2. At this time, the internal management data may include map information corresponding to a logical address-to-physical address included in a mapping table of the NVM device 200.

Thereafter, the second core 183 may perform a read operation on the NVM device 200 from a third time point t2+a and may output a callback message CB from a fourth time point t3+b. The third time point t2+a illustrated in FIG. 4 is faster than the third time point t3 illustrated in FIG. 3 as a time point delayed by “a” time from the second time point t2. The fourth time point t3+b illustrated in FIG. 4 is faster than the fourth time point t4 illustrated in FIG. 3 as a time point delayed by “b” time from the third time point t3. In other words, at the first time point t1, the first core 181 and the second core 183 both operate, so that execution is performed in parallel.

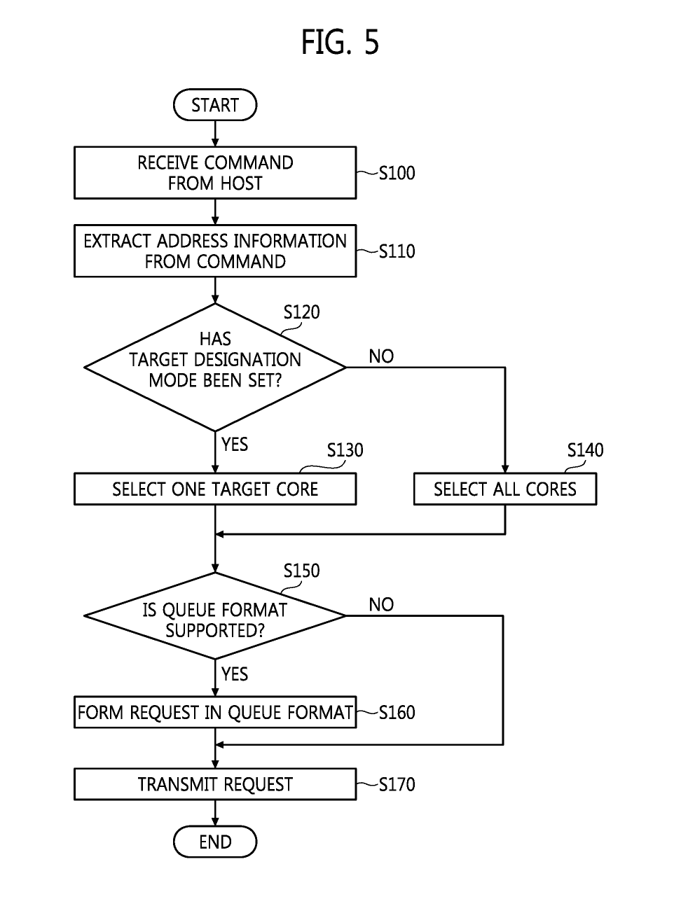

FIG. 5 is a flowchart of a method of operating the data storage device 300 according to one or more exemplary embodiments. Referring to FIGS. 1 through 5, the address extractor 170 may receive a command issued from the host 20 in operation S100 and may extract address information from the command in operation S110. The address extractor 170 may determine whether a target designation mode has been set based on the address information received in operation S120. When the target designation mode has been set, the address extractor 170 may select a target core of the plurality of second cores, i.e., a designated second core 183 in operation S130.

When it is determined that the target designation mode has not been set in operation S120, the address extractor 170 may select all of the plurality of second cores 183 in operation S140.

Thereafter, when the address information indicates the target designation mode, the address extractor 170 may determine whether the selected second core 183 supports the form of a queue, i.e., a queue format in operation S150. When the second core 183 supports the queue format, the address extractor 170 may form a request including the address information in a queue in operation S160, and may transmit the request in the queue to the selected second core 183 in operation S170. However, when the selected second core 183 does not support the queue format, the address extractor 170 may transmit a request including the address information to the selected second core 183 in operation S170.

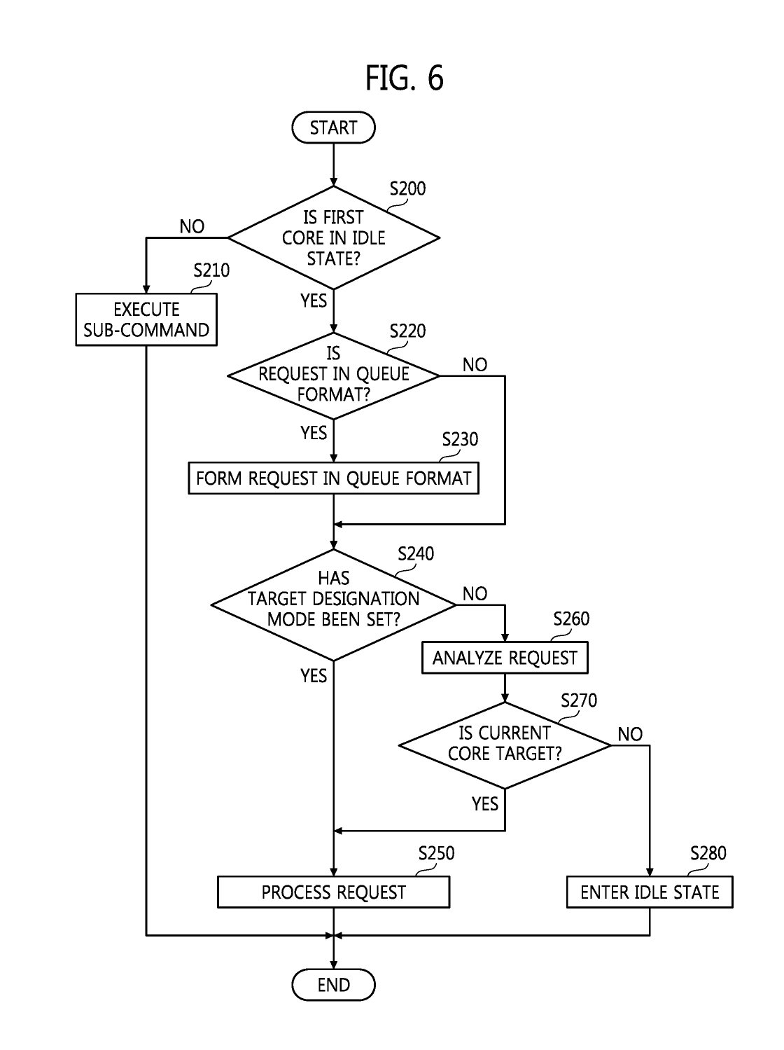

FIG. 6 is a flowchart of a method of operating the data storage device 300 according to one or more exemplary embodiments. FIG. 6 shows the operations of each of the plurality of second cores 183.

Referring to FIGS. 1 through 6, the second core 183 determines whether the first core 181 is in an idle state in operation S200. When the first core 181 is not in the idle state, the second core 183 may perform an operation corresponding to a sub-command received from the first core 181 in operation S210.

When it is determined that the first core 181 is in the idle state in operation S200, the second core 183 may determine whether a request can be processed in the queue format in operation S220. When a request can be processed in the queue format, the second core 183 forms requests in a queue in operation S230. In other words, when the queue format is supported, the second core 183 may sequentially process requests output from the address extractor 170. When the queue format is not supported, the second core 183 may process a unit request output from the address extractor 170.

The second core 183 may determine whether the target designation mode has been set based on the request received from the address extractor 170 in operation S240. When the target designation mode has been set, the second core 183 may perform an operation corresponding to the request received from the address extractor 170 in operation S250. When it is determined that the target designation mode has not been set in operation S240, the second core 183 may analyze the address information included in the request in operation S260, and may determine whether the address information corresponds to the second core 183 in operation S270.

When it is determined that the address information corresponds to the second core 183 in operation S270, the second core 183 may perform the operation corresponding to the request received from the address extractor 170 in operation S250. When the address information does not correspond to the second core 183, that is, the address information corresponds to not the current second core 183 but another second core of the plurality of second cores 183; the current second core 183 may enter the idle state in operation S280.

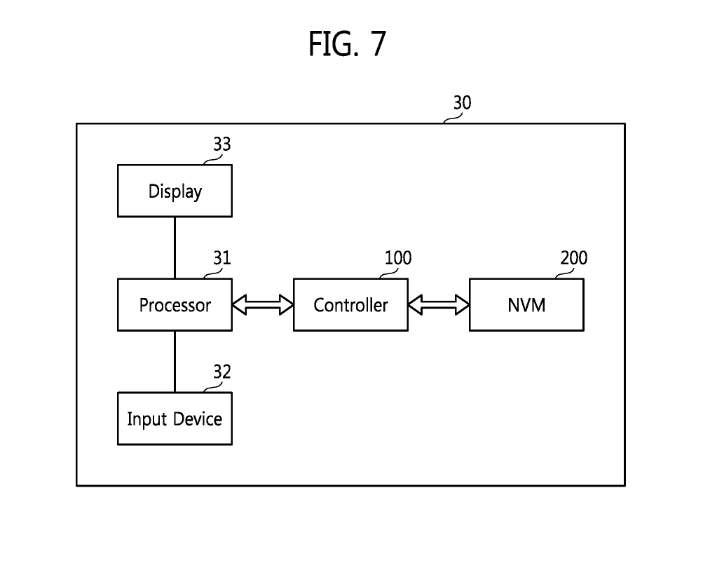

FIG. 7 is a block diagram of a data processing system 30 according to one or more exemplary embodiments. The data processing system 30 may be implemented as a PC, a tablet PC, a net-book, an e-reader, a personal digital assistant (PDA), a portable multimedia player (PMP), an MP3 player, or an MP4 player. The data processing system 30 includes the controller 100 and the NVM device 200. The controller 100 and the NVM device 200 may form the data storage device 300 illustrated in FIG. 2.

A processor 31 may cause a display 33 to display data stored in the NVM device 200 according to data input through an input device 32. The input device 32 may be implemented as a keypad, a keyboard, or a pointing device, such as a touch pad or a computer mouse. The processor 31 may control the overall operation of the data processing system 30 and may control the operation of the controller 100. The controller 100 may control the operation of the NVM device 200 and may be implemented as a part of the processor 31 or as a chip separate from the processor 31.

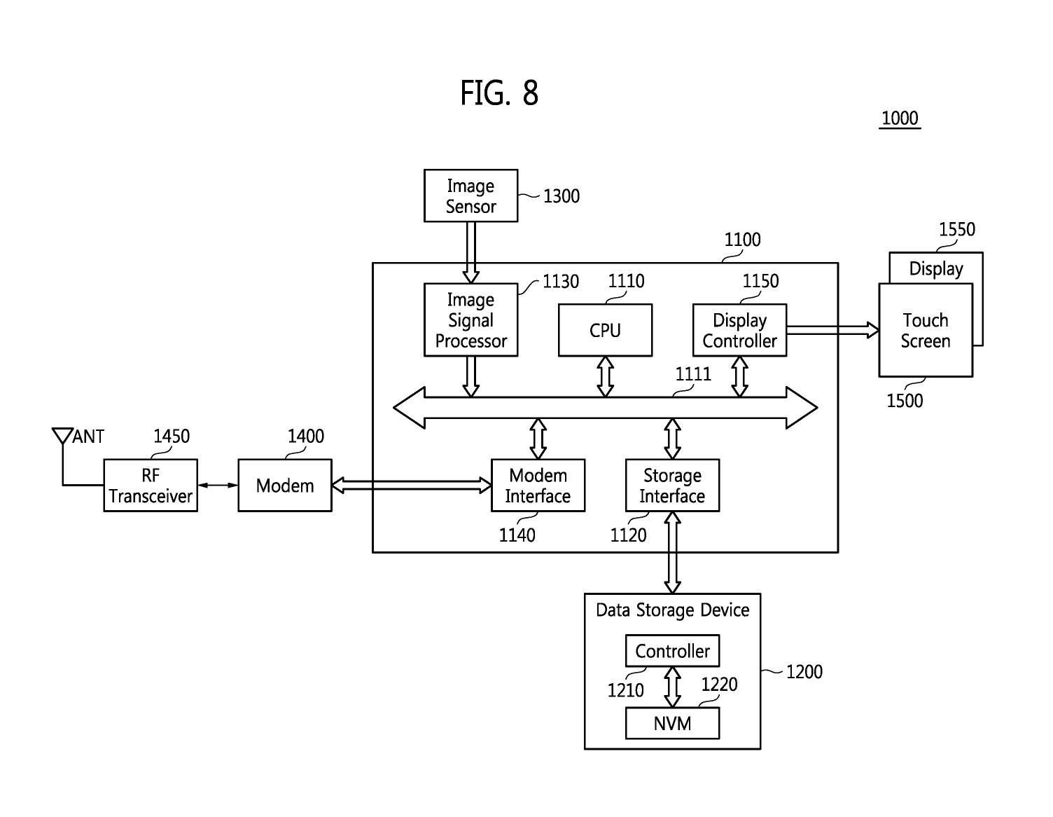

FIG. 8 is a block diagram of a data processing system 1000 according to one or more exemplary embodiments. Referring to FIGS. 1 through 8, the data processing system 1000 may be a mobile computing device. The mobile computing device may be a laptop computer, a cellular phone, a smart phone, a tablet PC, a PDA, an enterprise digital assistant (EDA), a digital still camera, a digital video camera, a PMP, a personal navigation device or portable navigation device (PND), a handheld game console, a MID, a wearable computer, an internet of things (IoT) device, an internet of everything (IoE) device, or an e-book.

The data processing system 1000 may include an application processor (AP) 1100, a data storage device 1200, an image sensor 1300, a modem 1400, a radio frequency (RF) transceiver 1450, and a display 1550 including a touch screen 1500. The data storage device 1200 may refer to the data storage device 300 illustrated in FIG. 2. A controller 1210 may refer to the controller 100 illustrated in FIG. 2 and an NVM device 1220 may refer to the NVM device 200 illustrated in FIG. 2.

The image sensor 1300 may convert an optical image into an electrical signal to generate image data. The RF transceiver 1450 may transmit radio data received through an antenna ANT to the modem 1400. The RF transceiver 1450 may convert data output from the modem 1400 into radio data and may transmit the radio data to an external device through the antenna ANT. The modem 1400 may process data transferred between the RF transceiver 1450 and the AP 1100.

The AP 1100 may control the data storage device 1200, the image sensor 1300, the modem 1400, the RF transceiver 1450, the touch screen 1500, and/or the display 1550. The AP 1100 may be implemented as an integrated circuit (IC), a system-on-chip (SoC), or a mobile AP.

The AP 1100 may include a central processing unit (CPU) 1110, bus architecture 1111, a storage interface 1120, an image signal processor 1130, a modem interface 1140, and a display controller 1150. The CPU 1110 may control the storage interface 1120, the image signal processor 1130, the modem interface 1140, and the display controller 1150 through the bus architecture 1111. The bus architecture 1111 may be implemented as AMBA, AHB, advanced peripheral bus (APB), AXI, or advanced system bus (ASB), but is not restricted to these examples.

The storage interface 1120 may control processing and/or transmission of data communicated with the data storage device 1200 according to the control of the CPU 1110. The image signal processor 1130 may receive and process image data output from the image sensor 1300, and transmit the processed image to the bus architecture 1111. The modem interface 1140 may control processing and/or transmission of data communicated with the modem 1400 according to the control of the CPU 1110.

The display controller 1150 may transmit data to be displayed to the display 1550 according to the control of the CPU 1110. The display controller 1150 and the display 1550 may communicate with each other using mobile industry processor interface (MIPI®) display serial interface. Alternatively, the display controller 1150 and the display 1550 may communicate with each other using an embedded DisplayPort (eDP).

The touch screen 1500 may transmit a user input signal corresponding to a user input for controlling the operation of the data processing system 1000 to the AP 1100. The user input may be generated by touching the touch screen 1500 of the data processing system 1000. The CPU 1110 may control the operations of the AP 1100, the image sensor 1300, and/or the display 1550 according to the user input signal transmitted from the touch screen 1500.

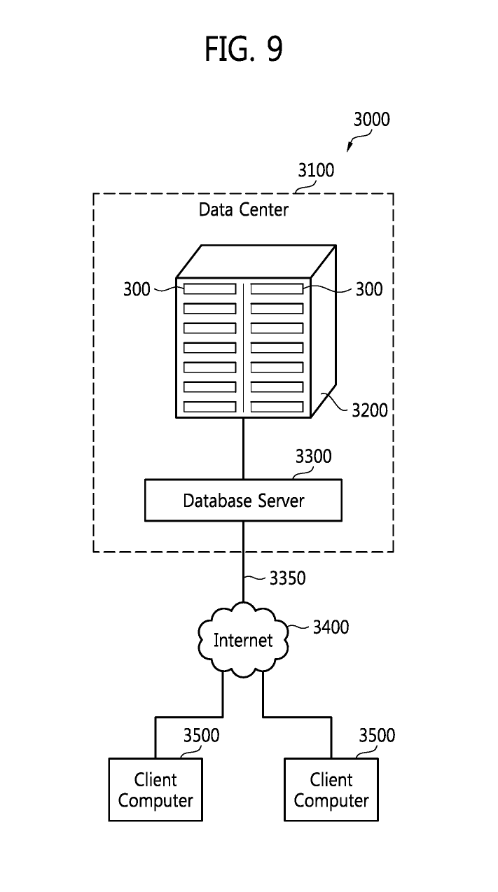

FIG. 9 is a block diagram of a data processing system 3000 according to one or more exemplary embodiments. Referring to FIGS. 1 through 9, the data processing system 3000 may include a database 3200, a database server 3300, a second network 3400, and a plurality of client computers 3500. The database 3200 and the database server 3300 may be included in a data center 3100. The data center 3100 may be an internet data center or a cloud data center.

The database 3200 may include a plurality of data storage devices 300. The data storage devices 300 may be installed in racks. The structure and operations of the data storage devices 300 are substantially the same as or similar to those of the data storage device 300 described above with reference to FIGS. 1 through 6.

The database server 3300 may control the operations of each of the data storage devices 300. The database server 3300 may be connected to the second network 3400, e.g., an internet, via a first network 3350, e.g., a local area network (LAN). The client computers 3500 may be connected to the database server 3300 via the second network 3400.

As described above, according to one or more exemplary embodiments, a data storage device operates a plurality of cores at the same time, thereby parallelizing processing. As a result, the performance of a system including the data storage device is increased.

The operations or steps of the methods or algorithms described above can be embodied as computer readable codes on a computer readable recording medium, or to be transmitted through a transmission medium. The computer readable recording medium is any data storage device that can store data which can be thereafter read by a computer system. Examples of the computer readable recording medium include read-only memory (ROM), random-access memory (RAM), compact disc (CD)-ROM, digital versatile disc (DVD), magnetic tape, floppy disk, and optical data storage device, not being limited thereto. The transmission medium can include carrier waves transmitted through the Internet or various types of communication channel. The computer readable recording medium can also be distributed over network coupled computer systems so that the computer readable code is stored and executed in a distributed fashion.

At least one of the components, elements, modules or units represented by a block as illustrated in FIG. 2 (e.g., address extractor 170, first core 181, second cores 183, etc.) may be embodied as various numbers of hardware, software and/or firmware structures that execute respective functions described above, according to an exemplary embodiment. For example, at least one of these components, elements, modules or units may use a direct circuit structure, such as a memory, a processor, a logic circuit, a look-up table, etc. that may execute the respective functions through controls of one or more microprocessors or other control apparatuses. Also, at least one of these components, elements, modules or units may be specifically embodied by a module, a program, or a part of code, which contains one or more executable instructions for performing specified logic functions, and executed by one or more microprocessors or other control apparatuses. Also, at least one of these components, elements, modules or units may further include or may be implemented by a processor such as a central processing unit (CPU) that performs the respective functions, a microprocessor, or the like. Two or more of these components, elements, modules or units may be combined into one single component, element, module or unit which performs all operations or functions of the combined two or more components, elements, modules or units. Also, at least part of functions of at least one of these components, elements, modules or units may be performed by another of these components, elements, modules or units. Further, although a bus is not illustrated in the above block diagrams, communication between the components, elements, modules or units may be performed through the bus. Functional aspects of the above exemplary embodiments may be implemented in algorithms that execute on one or more processors. Furthermore, the components, elements, modules or units represented by a block or processing steps may employ any number of related art techniques for electronics configuration, signal processing and/or control, data processing and the like.

While exemplary embodiments have been particularly shown and described, it will be understood by those of ordinary skill in the art that various changes in forms and details may be made therein without departing from the spirit and scope of the inventive concept as defined by the following claims.

What is claimed is:

1. A data storage device comprising:
a non-volatile memory device; and
a controller configured to receive a command from a host and to control an operation of the non-volatile memory device based on the command, the controller comprising a processor configured to receive and process the command and an address extractor configured to extract address information from the command and to output the address information to the processor before the processor processes the command.

2. The data storage device of claim 1, wherein the processor comprises:
a first core configured to generate a sub-command based on the command; and
a plurality of second cores configured to receive the sub-command output from the first core.

3. The data storage device of claim 2, wherein the sub-command corresponds to commands for controlling peripheral devices comprised in the data storage device to perform one of a read operation and a write operation of the non-volatile memory device.

4. The data storage device of claim 2, wherein the sub-command corresponds to one among a read operation, a write operation, and a trimming operation on peripheral devices comprised in the data storage device.

5. The data storage device of claim 2, wherein the address information comprises logical address information corresponding to peripheral devices comprised in the data storage device.

6. The data storage device of claim 5, wherein the logical address information comprises a namespace, a volume, a logical block address, and a length.

7. The data storage device of claim 2, wherein the first core is configured to determine the command at a first time point and the address extractor is configured to output the address information to the plurality of second cores at the first time point.

8. The data storage device of claim 7, wherein the plurality of second cores are configured to perform an operation of preparing to control peripheral devices comprised in the data storage device at the first time point based on the address information.

9. The data storage device of claim 8, wherein the plurality of second cores are configured to determine, at the first time point, whether internal management data corresponding to the address information has been loaded to the controller; and load, in response to the determining indicating the internal management data has not been loaded, the internal management data corresponding to the address information from the non-volatile memory device at a second time point after the first time point.

10. The data storage device of claim 9, wherein the sub-command comprise a command corresponding to an operation of loading the internal management data corresponding to the address information and a command corresponding to an operation of programming the non-volatile memory device based on the internal management data.

11. The data storage device of claim 10, wherein the internal management data comprises map information corresponding to the address information among information corresponding to a logical address and a physical address which are comprised in a mapping table of the non-volatile memory device.

12. The data storage device of claim 2, wherein each of the plurality of second cores is configured to determine whether to process the received sub-command based on the address information.

13. The data storage device of claim 12, wherein the address information indicates a selected second core of the plurality of second cores, and only the selected second core processes the received sub-command.

14. A method of operating a data storage device comprising a first core, a plurality of second cores and a non-volatile memory device, the method comprising:
receiving a command from a host;
extracting address information from the command;
determining whether a target designation mode has been set based on the address information extracted from the command;
transmitting a request comprising the address information to the plurality of second cores; and
processing, by the first core, the command to generate a sub-command.

15. The method of claim 14, further comprising determining whether the plurality of second cores support a queue format after the determining whether the target designation mode has been set;
forming a queue comprising the request, in response to determining the plurality of second cores support the queue format; and
transmitting the request in the queue to the plurality of second cores.

16. The method of claim 15, wherein the address information comprises logical address information corresponding to peripheral devices comprised in the data storage device; and the logical address information comprises a namespace, a volume, a logical block address, and a length.

17. The method of claim 14, further comprising, determining, by each of the plurality of second cores, whether the address information indicates the second core as a selected second core; and
processing, by only the selected second core, the request.

18. A method of operating a data storage device comprising a first core, a second core, a non-volatile memory device and an address extractor, the method comprising:
determining whether the first core is in an idle state;
receiving, using the second core, a request output from the address extractor;
determining, in response to the first core being in the idle state, using the second core, whether a target designation mode has been set based on the request output from the address extractor;
analyzing, in response to the determining indicating the target designation mode is not set, the request to determine a request target; and
performing an operation corresponding to the request in response to the analyzing indicating the second core is the request target.

19. The method of claim 18, further comprising performing, by the second core, an operation corresponding to a sub-command output from the first core in response to the determining indicating the first core is not in the idle state.

20. The method of claim 19, wherein the second core is one of a plurality of second cores, and the request target uniquely identifies the second core.
